(19) United States
(12) Patent Application Publication
(10) Pub. No.: US 2025/0210438 A1
(43) Pub. Date: Jun. 26, 2025

(54) METHOD AND APPARATUS FOR AMBIENT TEMPERATURE SENSOR DESIGN IN A COMPLEMENTARY METAL OXIDE SEMICONDUCTOR (CMOS) PROCESS

(71) Applicant: QUALCOMM Incorporated, San Diego, CA (US)

(72) Inventors: Abhijeet PAUL, San Diego, CA (US); Mishel MATLOUBIAN, San Diego, CA (US)

(21) Appl. No.: 18/391,364

(22) Filed: Dec. 20, 2023

(51) Int. Cl. H01L 23/34; H01L 27/092; H01L 29/40; H01L 29/73

(52) U.S. Cl. CPC H01L 23/34; H10D 10/00; H10D 64/111; H10D 84/85

(57) ABSTRACT

An integrated circuit (IC) structure is described. The IC structure includes a substrate having an active/passive device in the substrate. The IC structure also includes a terminal of the active/passive device in the substrate. The IC structure further includes a floating contact field plate above the terminal. The IC structure also includes a dielectric layer between the floating contact field plate and the terminal of the active/passive device.

### BACKGROUND

### Field

Aspects of the present disclosure relate to semiconductor devices and, more particularly, to a method and apparatus for ambient temperature sensor design in a complementary metal oxide semiconductor (CMOS) process.

### Background

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

Advanced logic CMOS scaling achieves a performance-power-area (PPA) boost over past process nodes. Unfortunately, further transistor mobility in smaller process nodes is difficult due to increased thermal junction temperatures. Additionally, measuring active device temperatures involves a direct connection to the active device, which adds the risk of electrical overstimulation (EOS), such as electrostatic discharge (ESD). Adding EOS/ESD protection elements introduces inaccuracy to the temperature measurement. When adding a non-connected (e.g., floating) metal on the active device, this non-connected metal is one interlayer dielectric (ILD) layer away from the transistor, which increases thermal resistance. Therefore, a method and apparatus for ambient temperature sensor design in a CMOS process is desired.

### SUMMARY

An integrated circuit (IC) structure is described. The IC structure includes a substrate having an active/passive device in the substrate. The IC structure also includes a terminal of the active/passive device in the substrate. The IC structure further includes a floating contact field plate above the terminal. The IC structure also includes a dielectric layer between the floating contact field plate and the terminal of the active/passive device.

A method for fabricating an ambient temperature sensing device using an integrated circuit (IC) structure is described. The method includes forming an active/passive device in a substrate. The method also includes forming a floating contact field plate above a terminal of the active/passive device. The method further includes depositing a dielectric layer between the floating contact field plate and the terminal of the active/passive device.

This has outlined, broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for conducting the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer, which may be used for fabricating a temperature sensing device, according to various aspects of the present disclosure.

FIG. 2 illustrates a cross-sectional view of the die of FIG. 1, which may be used for fabricating a temperature sensing device, according to various aspects of the present disclosure.

FIG. 3 illustrates a cross-sectional view of a metal oxide semiconductor field effect transistor (MOSFET) device.

FIG. 4 is a block diagram illustrating an ambient temperature sensing device utilizing an integrated circuit (IC) structure, according to various aspects of the present disclosure.

FIG. 5 further illustrates the ambient temperature sensing device utilizing the integrated circuit (IC) structure of FIG. 4, according to aspects of the present disclosure.

FIGS. 6A and 6B are diagrams illustrating an ambient temperature sensing device utilizing an integrated circuit (IC) structure, according to various aspects of the present disclosure.

FIG. 7 is a block diagram illustrating a complementary metal oxide semiconductor (CMOS) integrated circuit (IC) temperature sensing device, according to various aspects of the present disclosure.

FIGS. 8A and 8B are block diagrams illustrating alternative contact field plate (CFP) implementations of temperature sensing device, according to various aspects of the present disclosure.

FIG. 9 is a process flow diagram illustrating a method for fabricating an ambient temperature sensing device using an integrated circuit (IC) structure, according to various aspects of the present disclosure.

FIG. 10 is a block diagram showing an exemplary wireless communications system in which an aspect of the present disclosure may be advantageously employed.

FIG. 11 is a block diagram illustrating a design workstation used for circuit, layout, and logic design of an integrated circuit (IC) structure, such as the IC structure disclosed above.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

Advanced logic CMOS scaling achieves a performance-power-area (PPA) boost over past process nodes for fabricating CMOS transistors. Unfortunately, further transistor mobility in smaller process nodes is difficult due to increased thermal junction temperatures. Additionally, measuring active device temperatures involves a direct connection to the active device, which adds the risk of electrical overstimulation (EOS), such as electrostatic discharge (ESD). Adding EOS/ESD protection elements introduces inaccuracy to the temperature measurement. When adding a non-connected (e.g., floating) metal on the active device, this non-connected metal is one interlayer dielectric (ILD) layer away from the transistor, which increases thermal resistance. A method and apparatus for ambient temperature sensor design in a CMOS process is desired.

Various aspects of the present disclosure are directed to a method and apparatus for an ambient temperature sensor design in a CMOS process. The process flow for fabricating an ambient temperature sensing device may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

A temperature sensing device utilizes an integrated circuit (IC) structure, including a substrate having an active/passive device in the substrate. The IC structure includes a terminal of the active device in the substrate. Additionally, the IC structure includes a floating contact field plate on the terminal. The IC structure further includes a dielectric layer between the contact field plate (CFP) and the terminal to provide a direct thermal contact between the terminal and the floating contact field plate. In various aspects of the present disclosure, a first (M1) metal layer is coupled to the floating contact field plate to provide a thermal terminal of the temperature sensing device.

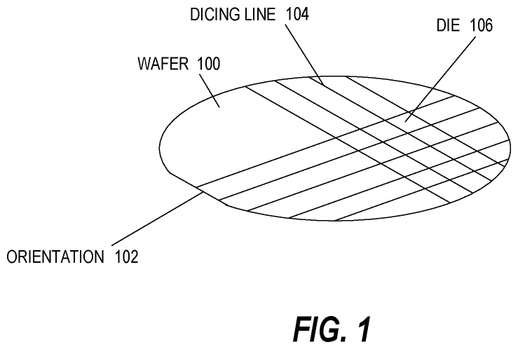

FIG. 1 illustrates a perspective view of a semiconductor wafer, which may be used for fabricating a temperature sensing device, according to various aspects of the present disclosure. A wafer 100 may be a semiconductor wafer or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a single material (e.g., silicon (Si), germanium (Ge)) or a compound material, such as gallium arsenide (GaAs), gallium nitride (GaN), or indium phosphide (InP), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, diverse types of electronic devices may be formed in or on the wafer 100.

The wafer 100 has an orientation 102 that indicates the crystalline orientation of the wafer 100. The orientation 102 may be a flat edge of the wafer 100 as shown in FIG. 1 or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and €, which are the Miller indices for a plane (hk ( ) in the crystal. Each index denotes a plane orthogonal to a direction (h, k, €) on the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to €. For some crystals, negative numbers are used (written as a bar over the index number) and for some crystals, such as gallium nitride, more than three numbers may be employed to describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

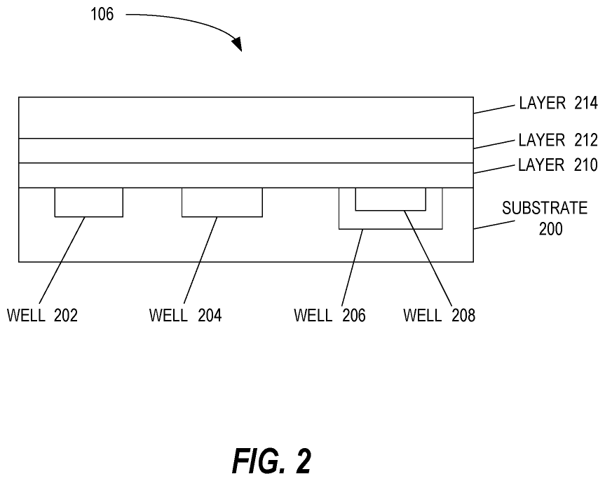

FIG. 2 illustrates a cross-sectional view of the die 106 of FIG. 1, which may be used for fabricating a temperature sensing device, according to various aspects of the present disclosure. In the die 106, there may be a substrate 200, which may be a semiconductor material and/or may function as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within the substrate 200 (e.g., a semiconductor substrate), there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT), which may be used for formation of an ambient temperature sensing device. The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may be composed of a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

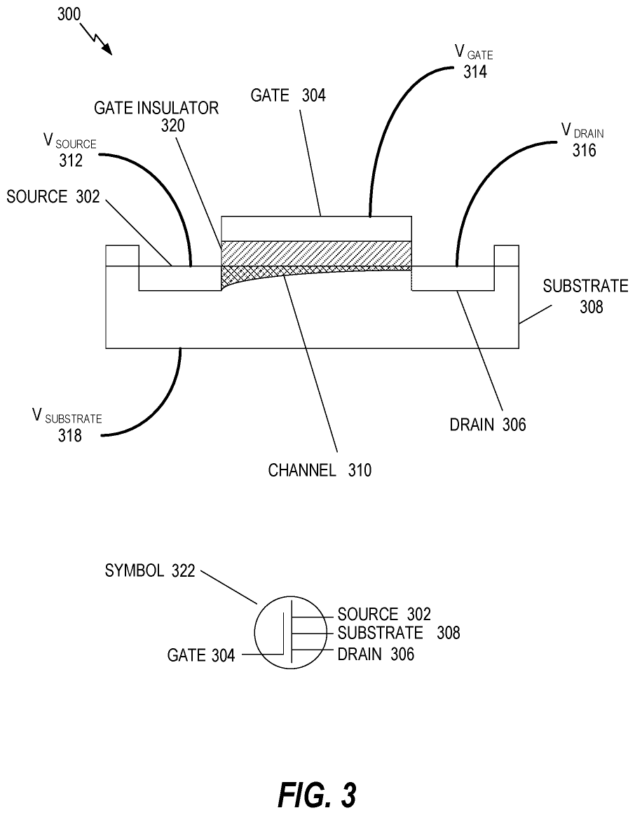

FIG. 3 illustrates a cross-sectional view of a metal oxide semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308 or may be fabricated as areas above the substrate 308, or as part of other layers on the die 106 of FIG. 1. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For P-type MOSFETs (using holes as charge carriers in the channel 310), an arrow is applied to the substrate 308 terminal in the symbol 322 pointing toward the gate 304 terminal.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304, as described below.

To interconnect to the MOSFET device 300, or to interconnect to other devices in the die 106 (e.g., semiconductor), interconnect traces or layers are used. These interconnect traces may be in one or more layers (e.g., 210-214), or may be in other layers of the die 106.

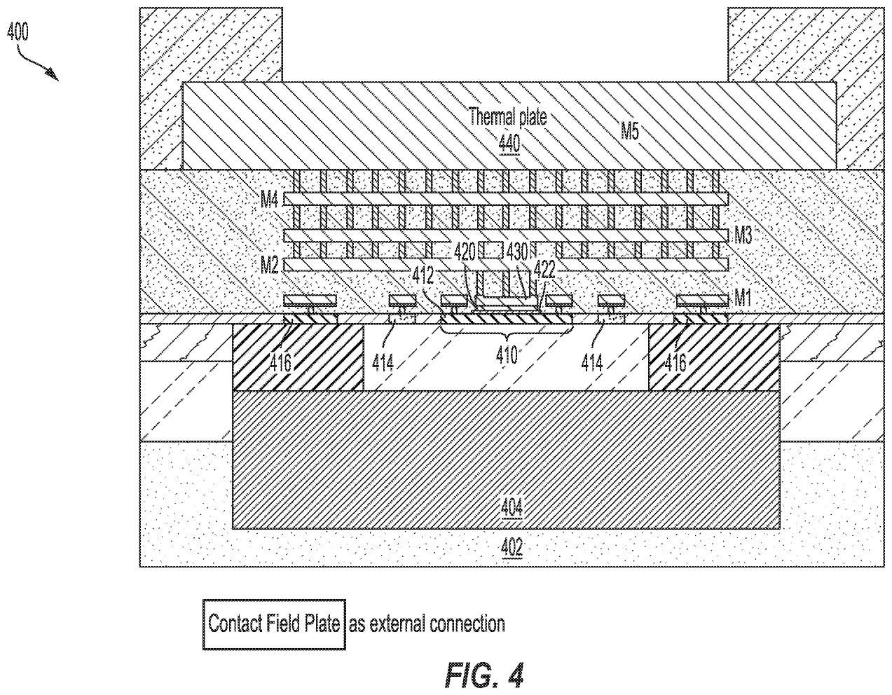

Sensing ambient temperature from an active device (e.g., the die 106 and/or MOSFET device 300) involves a metal sensing plate that is open to an outside environment. A concern with utilizing a metal sensing plate is the possibility of a short occurring in an internal complementary metal oxide semiconductor (CMOS) die. Another concern with utilizing a metal sensing plate is the threat of electrostatic discharge (ESD) failures. In response, various aspects of the present disclosure are directed to a method of fabricating an ambient temperature sensor utilizing a metal sensing plate that relies on a thermal connection to an active sensing device (e.g., bipolar junction transistor (BJT)/diode/MOSFET) without electrical connection for electrostatic discharge (ESD) protection. In various aspects of the present disclosure, a dielectric prevents direct electrical connection with the active device, while maintaining a thermal contact to the active device through the dielectric. Additionally, field plates, which are used for the production of multiple technologies are utilized. In operation, field plates are fabricated using a separate mask and interconnect layer or using an existing layer such as a contact field plate, for example, as shown in FIG. 4.

FIG. 4 is a block diagram illustrating an ambient temperature sensing device utilizing an integrated circuit (IC) structure 400, according to various aspects of the present disclosure. As shown in FIG. 4, the IC structure 400 includes a substrate 402 having an active device 410 in the substrate 402, including a buried layer 404 (e.g., an N-type buried layer (NBL)). In this example, the IC structure 400 includes a terminal 412 of the active device 410 in the substrate 402. In various aspects of the present disclosure, the IC structure 400 includes a contact field plate 420 on the terminal 412. The IC structure 400 further includes a dielectric layer 422 (e.g., silicon nitride (SiN), silicon dioxide (SiO₂), titanium nitride (TiN)) between the contact field plate 420 and the terminal 412. In various aspects of the present disclosure, the dielectric layer 422 provides a thermal contact directly between the terminal 412 and the contact field plate 420, in which a thickness of the dielectric layer 422 can range from three hundred (300) to eight hundred (800) angstroms (Å). Additionally, a first (M1) metal layer is coupled to the contact field plate 420 and provides a thermal terminal 430 of the temperature sensing device.

As further illustrated in FIG. 4, a second (M2) metal layer, a third (M3) metal layer, and a fourth (M4) metal layer provide an external path from the active device 410 through the thermal terminal 430. In this example, the M2 metal layer, the M3 metal layer, and the M4 metal layer provide an external path from the thermal terminal 430 to a thermal plate 440 formed from a fifth (M5) metal layer. The M1 metal layer, the M2 metal layer, the M3 metal layer, the M4 metal layer, and the M5 metal layer may be composed of a conductive material such as copper, tungsten, aluminum, an alloy, or other conductive or metallic materials. Although shown to include five metal layers, it should be recognized that different configurations of the IC structure 400 may have a different number of metal layers. In various aspects of the present disclosure, the active device 410 is implemented as a metal-oxide-semiconductor (MOS) field effect transistor (FET) (MOSFET) and the terminal 412 is a drain terminal of the MOSFET. Alternatively, the active device 410 is implemented as a diode and the terminal 412 is an anode or a cathode of the diode.

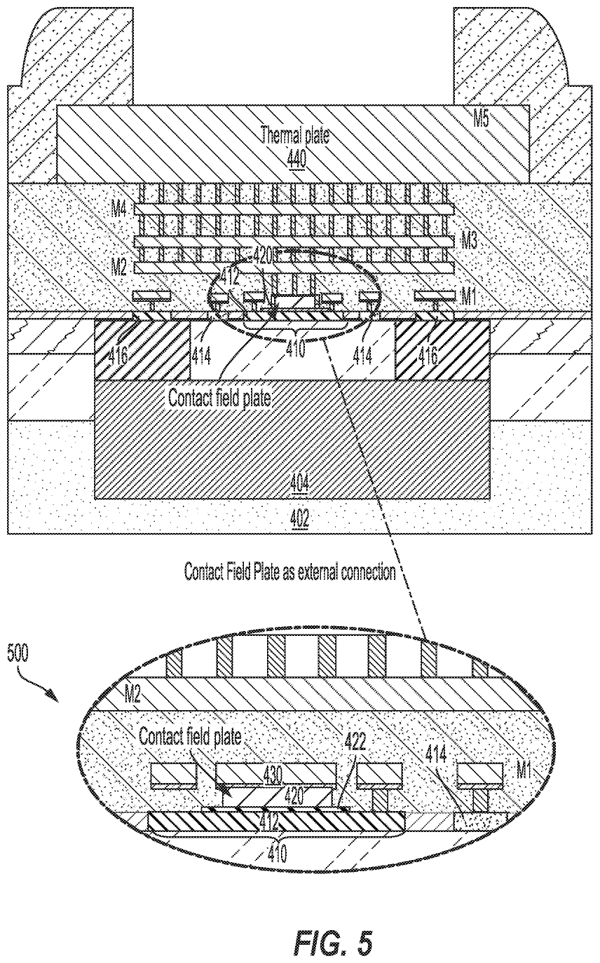

FIG. 5 further illustrates the ambient temperature sensing device utilizing the integrated circuit (IC) structure 400 of FIG. 4, according to aspects of the present disclosure. As shown in FIG. 5, an exploded view 500 further illustrates the contact field plate 420, according to various aspects of the present disclosure. As shown in FIG. 5, the active device 410 is an emitter of a bipolar junction transistor, including bases 414 and collectors 416. In this example, the collectors 416 are formed from the buried layer 404 (e.g., an N-type buried layer (NBL)). Additionally, the bases 414 are formed in a P-type diffusion region, and the emitter (e.g., terminal 412) is formed in an N-type region. In this example, the thermal plate 440 is implemented as an emitter plate; however, other configurations are possible in which the thermal plate 440 is on the collectors 416 based on the final design of the IC structure 400 as well as sensor specifications.

In various aspects of the present disclosure, the emitter plate (e.g., the thermal plate 440) is open to an external environment for providing an ambient temperature sensing plate. This ambient temperature sensing plate prevents vulnerability to electrostatic discharge (ESD). Additionally, the thermal plate 440 is electrically isolated from the active device 410 using the contact field plate 420. This configuration significantly reduces thermal resistance. The reduced thermal resistance provides improved temperature sensitivity from the thermal plate 440 and is enabled without extra masks during fabrication.

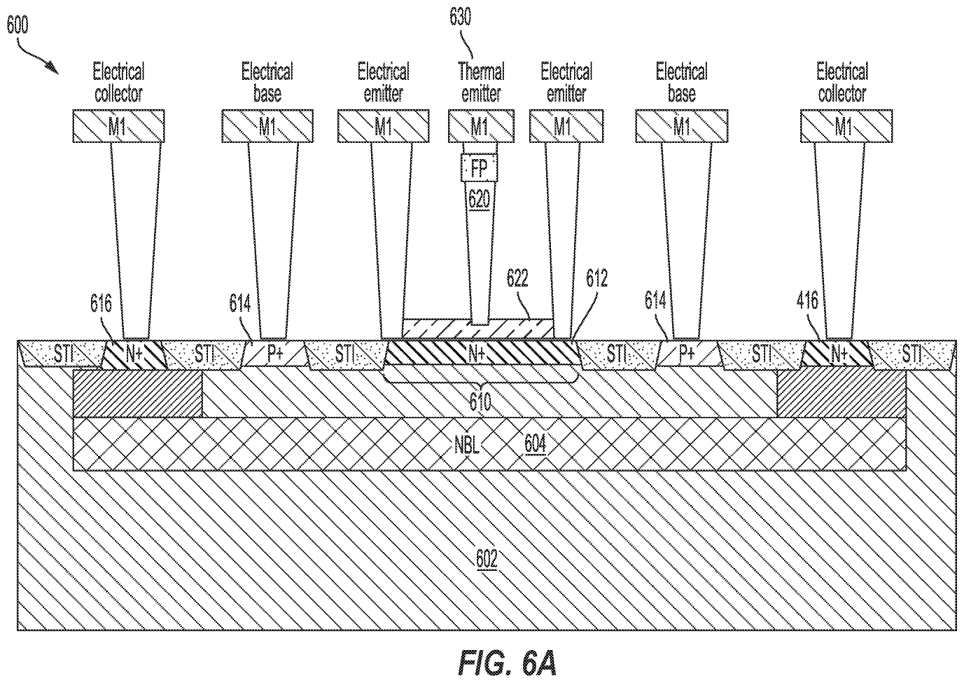

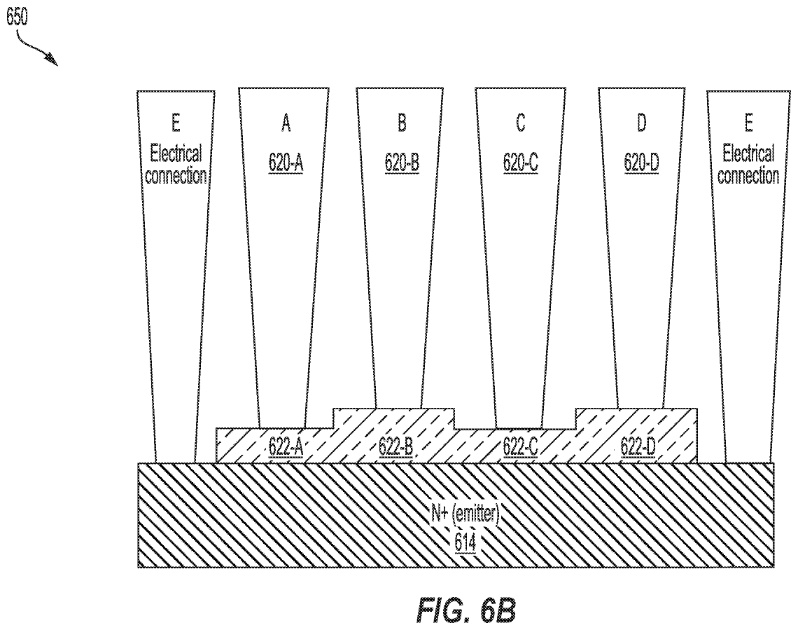

FIGS. 6A and 6B are diagrams illustrating an ambient temperature sensing device utilizing an integrated circuit (IC) structure 600, according to various aspects of the present disclosure. As shown in FIG. 6A, the IC structure 600 includes a substrate 602 having an active device 610 (e.g., a bipolar junction transistor (BJT)) in the substrate 602, including an N-type buried layer (NBL) 604). In this example, the IC structure 600 includes a terminal 612 (e.g., an emitter) of the active device 610 in the substrate 602. In various aspects of the present disclosure, the IC structure 600 includes a floating contact field plate 620 on the terminal 612.

The IC structure 600 further includes a dielectric layer 622 between the floating contact field plate 620 and the terminal 612 to provide a thermal contact directly between the terminal 612 and the floating contact field plate 620. Additionally, a first (M1) metal layer couples to the floating contact field plate 620 and provides a thermal terminal 630 (e.g., a thermal emitter) of the temperature sensing device utilizing the IC structure 600. Additionally, this configuration of the IC structure 600 provides better electrostatic discharge (ESD) protection, but reduces a temperature of the terminal 612, which depends on the thickness (e.g., 1000 angstroms (Å)) of the dielectric layer 622 on which the floating contact field plate 620 lands. Although shown with respect to a BJT implementation, the IC structure 600 may be applied to a P-N junction diode, with the floating contact field plate 620 on an N+ region of the diode as well as a diode connect FET, in which the floating contact field plate 620 is on a drain region (e.g., impacting the drain side).

TABLE I
Film Thickness Variation to Increase/Decrease Thermal Resistance

| Terminal name | Film thickness | Thermal resistance | comments |
|---|---|---|---|
| A, C | Thin (e.g., ^{~}300A) | Smaller (Rth_a, Rth_c) | Thermal resistance |
| B, D | Thick (e.g., ^{~}800A) | Higher (Rth_b, Rth_d) | Thermal resistance |
| E | None | NA | Electrical contact |

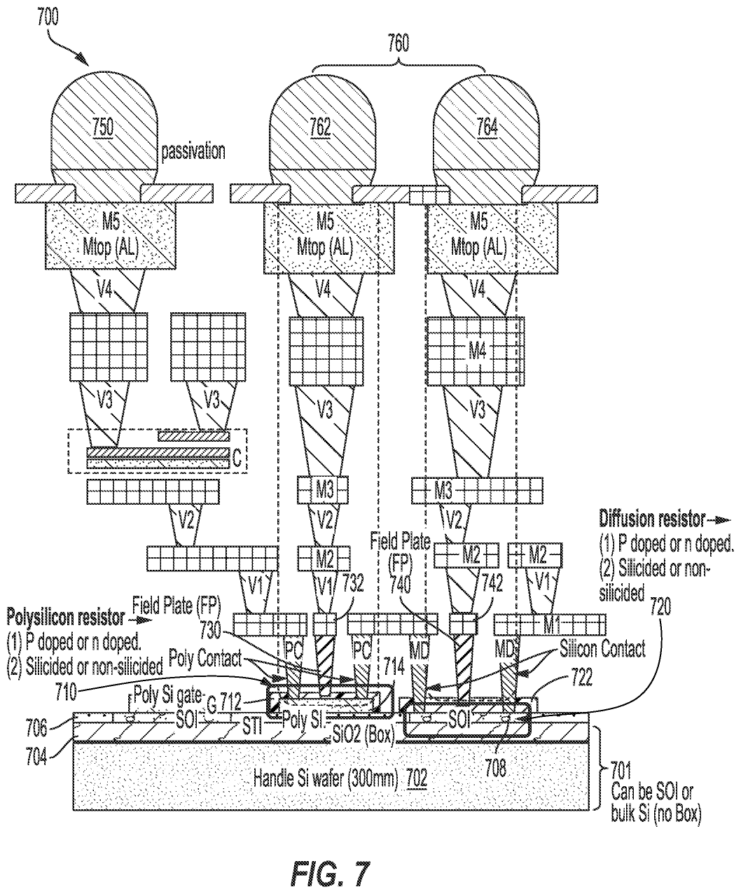

FIG. 6B, illustrates exploded view 650 of the IC structure 600 to further illustrate reuse of the field plate as a thermal contact for the terminal 612 (e.g., a BJT emitter/diode) for sensing an external temperature. In operation, sensing temperature from the terminal 612 is controlled by adjusting a thickness of the dielectric layer 622 as well as a contact area. The exploded view illustrates a variable thickness dielectric layer 622 (e.g., 622-A, 622-B, 622-C, 622-D) each associated with a corresponding contact field plate 620 (e.g., 620-A, 620-B, 620-C, 620-D). As shown Table I, a thickness of the dielectric 622 under the contact field plate 620 is variable, which allows for differential thermal resistance (Rthemal). For example, as shown in Table I, dielectric portions 622-A and 622-C corresponding to CFPs 620-A and 620-C have a reduced dielectric film thickness (e.g., ˜300 A), resulting in a reduced thermal thickness (Rthermal_a, Rthermal_c). Conversely, as shown in Table I, dielectric portions 622-B and 622-D corresponding to CFPs 620-B and 620-D have an increased dielectric film thickness (e.g., ˜800 A), resulting in an increased thermal resistance (Rthermal_b, Rthermal_d). According to various aspects of the present disclosure, the variable thickness dielectric layer 622 under the contact field plate 622 enables uniform/gradient based temperature (e.g., emitter temperature. A process of fabricating the IC structure 600 is illustrated, for example, in FIG. 7.

FIG. 7 is a block diagram illustrating a complementary metal oxide semiconductor (CMOS) integrated circuit (IC) temperature sensing device 700, according to various aspects of the present disclosure. As shown in FIG. 7, the IC temperature sensing device 700 includes a semiconductor-on-insulator (SOI) substrate 701 having a buried oxide (BOX) layer 704 on a handle wafer 702. Additionally, the SOI substrate 701 includes an SOI layer 708, separated by shallow trench isolation (STI) layers 706, on the BOX layer 704. Although shown as the SOI substrate 701, it should be recognized that the IC temperature sensing device 700 may be implemented using a bulk substrate, such as a bulk silicon (Si) substrate.

As shown in FIG. 7, the IC temperature sensing device 700 includes a polysilicon gate (G) on the SOI layer 708. Additionally, the IC temperature sensing device 700 includes a first resistor 710 on the STI layer 706, and a second resistor 720 on the SOI layer 708. In this example, the first resistor 710 is a polysilicon resistor, having a polysilicon layer 714, which may be P-type doped or N-type doped. Additionally, the second resistor 720 is a diffusion resistor, including the SOI layer 708, which may be P-type doped or N-type doped. Although described with reference to the first resistor 710 and the second resistor 720, a CMOS capacitor (MOSCAP) is also contemplated according to various aspects of the present disclosure.

In various aspects of the present disclosure, the IC temperature sensing device 700 includes a first contact field plate 730 on the polysilicon layer 714. The IC temperature sensing device 700 further includes a dielectric layer 712 (e.g., titanium nitride (TiN)) between the first contact field plate 730 and the polysilicon layer 714 to provide a thermal contact directly between the polysilicon layer 714 and the first contact field plate 730. Additionally, a first (M1) metal layer is coupled to the first contact field plate 730 for providing a first thermal terminal 732 of the IC temperature sensing device 700. The M1 metal layer is also contacted to the polysilicon layer 714 through poly contacts (PC), using a silicided contact or a non-silicided contact.

Additionally, the IC temperature sensing device 700 includes a second contact field plate 740 on the SOI layer 708. The IC temperature sensing device 700 further includes a dielectric layer 722 (e.g., titanium nitride (TiN)) between the second contact field plate 740 and the SOI layer 708 to provide a thermal contact directly between the SOI layer 708 and the second contact field plate 740. Additionally, a first (M1) metal layer is coupled to the second contact field plate 740 and provides a second thermal terminal 742 of the IC temperature sensing device 700. The M1 metal layer is also contacted to the SOI layer 708 through metal to diffusion (MD) contacts, using a silicided contact or a non-silicided contact.

As further illustrated in FIG. 7, a first (V1) via, a second (M2) metal layer, a second (V2) via, a third (M3) metal layer, a third (V3) via, a fourth (M4) metal layer, a fourth (V4) via, and a fifth (M5) metal layer provide an external path from the first resistor 710 through the first thermal terminal 732. In this example, the V1 via, the M2 metal layer, the V2 via, the M3 metal layer, the V3 via, the M4 metal layer, the V4 via, and the M5 metal layer provide an external path from the first thermal terminal 732 to a first external temperature sense bump 762 of a pair external temperature sense bumps 760. Additionally, a V1 via, an M2 metal layer, a V2 via, an M3 metal layer, a V3 via, a M4 metal layer, the V4 via, and the M5 metal layer provide an external path from the second resistor 720 through the second thermal terminal 742. In this example, the V1 via, the M2 metal layer, the V2 via, the M3 metal layer, the V3 via, the M4 metal layer, the V4 via, and the M5 metal layer provide an external path from the second thermal terminal 742 to a second external temperature sense bump 764 of the pair external temperature sense bumps 760.

As further illustrated in FIG. 7, a V1 via, an M2 metal layer, a V2 via, an M3 metal layer, a V3 via, a M4 metal layer, the V4 via, and the M5 metal layer provide an external path from the first resistor 710 to an electrical bump 750. In this example, a capacitor (C) is formed between the M3 metal layer and V3 vias. Although shown two include five metal layers, it should be recognized that different configurations of the IC temperature sensing device 700 may have a different number of metal layers. The V1 via, the M2 metal layer, the V2 via, the M3 metal layer, the V3 via, the M4 metal layer, the V4 via, and the M5 metal layer may be composed of a conductive material such as copper, tungsten, aluminum, an alloy, or other conductive or metallic materials. In this example, the M5 metal layer is shown as composed of aluminum (Al).

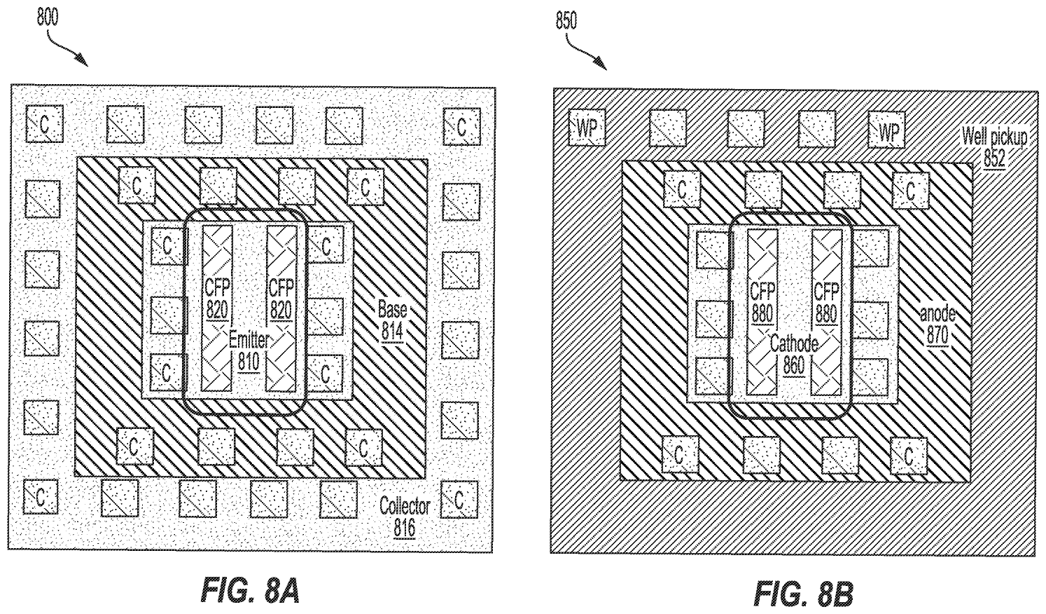

FIGS. 8A and 8B are block diagrams illustrating alternative contact field plate (CFP) implementations of temperature sensing device, according to various aspects of the present disclosure. In various aspects of the present disclosure, a temperature sensing device 800 includes a contact field plate 820 on a terminal 412 of an active device 810. As shown in FIG. 8A, the active device 810 is an emitter of a bipolar junction transistor (BJT), including base layer 814 and a collector layer 816. In this example, the collector layer 816 is formed from an N-type semiconductor (e.g., an N-type buried layer (NBL) of silicon (Si)). Additionally, the bases 414 are formed in a P-type diffusion region, and the emitter (e.g., terminal 412) is formed in an N-type region. In this example, electrical contacts (C) are also shown.

In various aspects of the present disclosure, a temperature sensing device 850 includes a contact field plate 820 on a terminal of an active device 860. As shown in FIG. 8B, the active device 860 is a cathode of a diode, including an anode 870 in a well region 852 (e.g., a P-type well of silicon). In this example, the anode 870 is in a P-type diffusion region (e.g., a P-type silicon (Si)). Additionally, the cathode is formed in an N-type diffusion region (e.g., an N-type silicon (Si)). In this example, the well region 852 includes well pickups (WP), and electrical contacts (C) are also shown.

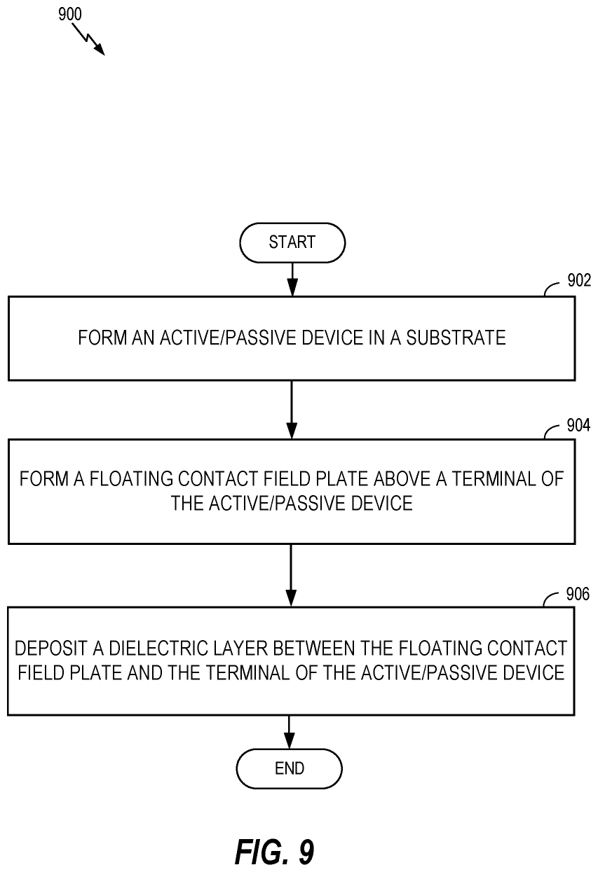

FIG. 9 is a process flow diagram illustrating a method 900 for fabricating an ambient temperature sensing device using an integrated circuit (IC) structure, according to various aspects of the present disclosure. The method 900 begin at block 902, in which an active/passive device is formed in a substrate. For example, as shown in FIG. 4, the IC structure 400 includes the substrate 402 having the active device 410 in the substrate 402, including the buried layer 404 (e.g., the N-type buried layer (NBL)). As shown in FIG. 7, the IC temperature sensing device 700 includes the first resistor 710 on the STI layer 706, and the second resistor 720 on the SOI layer 708.

At block 904, a floating contact field plate is formed above a terminal of the active/passive device. For example, as shown in FIG. 6, the IC structure 600 includes a terminal 612 (e.g., an emitter) of the active device 610 in the substrate 602. In various aspects of the present disclosure, the IC structure 600 includes a floating contact field plate 620 on the terminal 612. As shown in FIG. 7, the IC temperature sensing device 700 includes the first contact field plate 730 on the polysilicon layer 714.

At block 906, a dielectric layer is deposited between the floating contact field plate and the terminal of the active/passive device. For example, as shown in FIG. 4, the IC structure 400 further includes a dielectric layer 422 (e.g., silicon nitride (SiN), silicon dioxide (SiO₂), titanium nitride (TiN)) between the contact field plate 420 and the terminal 412. In various aspects of the present disclosure, the dielectric layer 422 provides a thermal contact directly between the terminal 412 and the contact field plate 420, in which a thickness of the dielectric layer 422 can range from three hundred (300) to eight hundred (800) angstroms (Å). As shown in FIG. 7, the IC temperature sensing device 700 includes the dielectric layer 722 (e.g., titanium nitride (TiN)) between the second contact field plate 740 and the SOI layer 708 to provide a thermal contact directly between the SOI layer 708 and the second contact field plate 740.

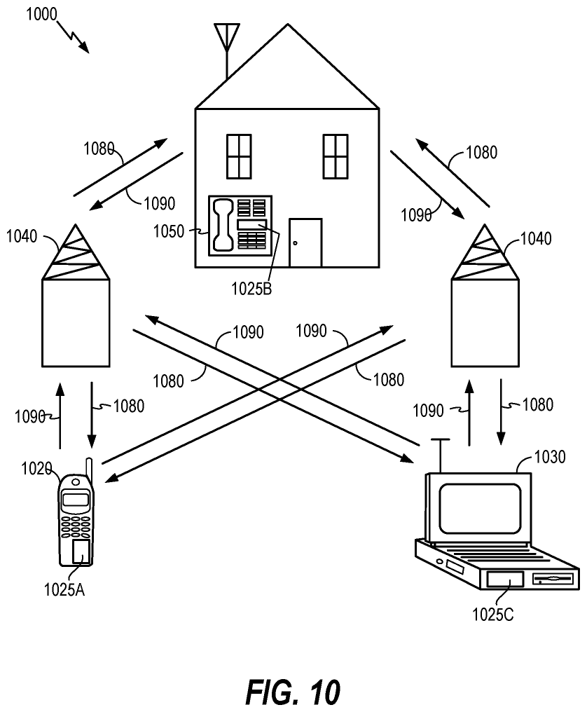

FIG. 10 is a block diagram showing an exemplary wireless communications system 1000 in which an aspect of the present disclosure may be advantageously employed. For purposes of illustration, FIG. 10 shows three remote units 1020, 1030, and 1050, and two base stations 1040. It will be recognized that wireless communications systems may have many more remote units and base stations. Remote units 1020, 1030, and 1050 include IC devices 1025A, 1025C, and 1025B that include the disclosed IC structure. It will be recognized that other devices may also include the disclosed IC structure, such as the base stations, switching devices, and network equipment. FIG. 10 shows forward link signals 1080 from the base station 1040 to the remote units 1020, 1030, and 1050, and reverse link signals 1090 from the remote units 1020, 1030, and 1050 to base station 1040.

In FIG. 10, remote unit 1020 is shown as a mobile telephone, remote unit 1030 is shown as a portable computer, and remote unit 1050 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 10 illustrates remote units according to the aspects of the disclosure, the disclosure is not limited to these exemplary illustrated units. Aspects of the disclosure may be suitably employed in many devices, which include the disclosed IC structure.

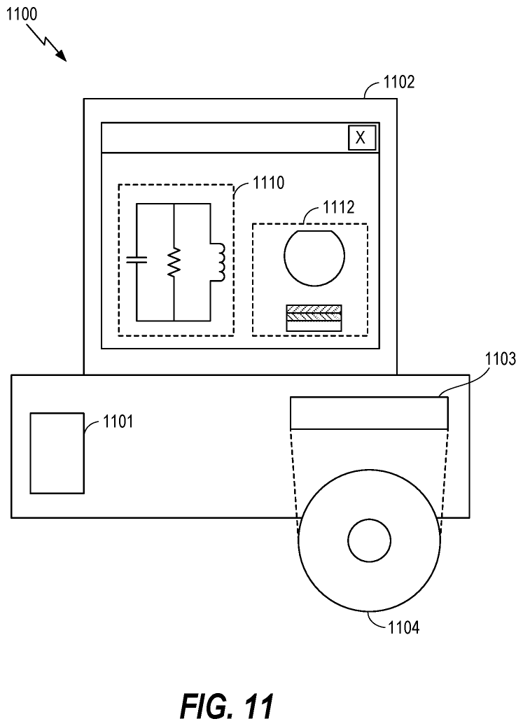

FIG. 11 is a block diagram illustrating a design workstation used for circuit, layout, and logic design of an integrated circuit (IC) structure, such as the IC structure disclosed above. A design workstation 1100 includes a hard disk 1101 containing operating system software, support files, and design software such as Cadence or OrCAD. The design workstation 1100 also includes a display 1102 to facilitate design of a circuit 1110 or an IC structure 1112 including an IC structure. A storage medium 1104 is provided for tangibly storing the design of the circuit 1110 or the IC structure 1112. The design of the circuit 1110 or the IC structure 1112 may be stored on the storage medium 1104 in a file format such as GDSII or GERBER. The storage medium 1104 may be a CD-ROM, DVD, hard disk, flash memory, or other appropriate device. Furthermore, the design workstation 1100 includes a drive apparatus 1103 for accepting input from or writing output to the storage medium 1104.

Data recorded on the storage medium 1104 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1104 facilitates the design of the circuit 1110 or the IC structure 1112 by decreasing the number of processes for designing semiconductor wafers.

Implementation examples are described in the following numbered clauses:

1. An integrated circuit (IC) structure, comprising:
a substrate;
a terminal of an active/passive device in the substrate;
a floating contact field plate above the terminal; and
a dielectric layer between the floating contact field plate and the terminal of the active/passive device.

2. The IC structure of clause 1, in which the active/passive device comprises a bipolar junction transistor (BJT) and the terminal comprises an emitter.

3. The IC structure of clause 1, in which the active/passive device comprises a complementary metal oxide semiconductor (CMOS), diffusion resistor, a CMOS, polysilicon resistor, and/or a CMOS capacitor (MOSCAP).

4. The IC structure of clause 1, in which the active/passive device comprises a diode and the terminal comprises an anode or a cathode.

5. The IC structure of any of clauses 1-4, in which the dielectric layer comprises silicon nitride (SiN), silicon dioxide (SiO₂), or titanium nitride (TiN).

6. The IC structure of any of clauses 1-5, in which the floating contact field plate comprises tungsten (W), cobalt (Co), or ruthenium (Ru).

7. The IC structure of any of clauses 1-6, further comprising a first (M1) metal layer coupled to the floating contact field plate.

8. The IC structure of any of clauses 1 or 2, further comprising a first (M1) metal layer comprising a thermal emitter.

9. The IC structure of clause 8, further comprising an emitter plate coupled to the thermal emitter.

10. The IC structure of any of clauses 1-9, in which the dielectric layer comprises a direct thermal contact between the terminal and the floating contact field plate.

11. A method for fabricating an ambient temperature sensing device using an integrated circuit (IC) structure, the method comprising:
forming an active/passive device in a substrate;
forming a floating contact field plate above a terminal of the active/passive device; and
depositing a dielectric layer between the floating contact field plate and the terminal of the active/passive device.

12. The method of clause 11, in which the active/passive device comprises a bipolar junction transistor (BJT) and the terminal comprises an emitter.

13. The method of clause 11, in which the active/passive device comprises a complementary metal oxide semiconductor (CMOS), diffusion resistor, a CMOS, polysilicon resistor, and/or a CMOS capacitor (MOSCAP).

14. The method of clause 11, in which the active/passive device comprises a diode and the terminal comprises an anode or a cathode.

15. The method of any of clauses 11-14, in which the dielectric layer comprises silicon nitride (SiN), silicon dioxide (SiO₂), or titanium nitride (TiN).

16. The method of any of clauses 11-15, in which the floating contact field plate comprises tungsten (W), cobalt (Co), or ruthenium (Ru).

17. The method of any of clauses 11-16, further comprising a first (M1) metal layer coupled to the floating contact field plate.

18. The method of any of clauses 11 or 12, further comprising a first (M1) metal layer comprising a thermal emitter.

19. The method of clause 18, further comprising an emitter plate coupled to the thermal emitter.

20. The method of any of clauses 11-19, in which the dielectric layer comprises a direct thermal contact between the terminal and the floating contact field plate.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC) structure, comprising:
a substrate;
a terminal of an active/passive device in the substrate;
a floating contact field plate above the terminal; and
a dielectric layer between the floating contact field plate and the terminal of the active/passive device.

2. The IC structure of claim 1, in which the active/passive device comprises a bipolar junction transistor (BJT) and the terminal comprises an emitter.

3. The IC structure of claim 1, in which the active/passive device comprises a complementary metal oxide semiconductor (CMOS), diffusion resistor, a CMOS, polysilicon resistor, and/or a CMOS capacitor (MOSCAP).

4. The IC structure of claim 1, in which the active/passive device comprises a diode and the terminal comprises an anode or a cathode.

5. The IC structure of claim 1, in which the dielectric layer comprises silicon nitride (SiN), silicon dioxide (SiO₂), or titanium nitride (TiN).

6. The IC structure of claim 1, in which the floating contact field plate comprises tungsten (W), cobalt (Co), or ruthenium (Ru).

7. The IC structure of claim 1, further comprising a first (M1) metal layer coupled to the floating contact field plate.

8. The IC structure of claim 1, further comprising a first (M1) metal layer comprising a thermal emitter.

9. The IC structure of claim 8, further comprising an emitter plate coupled to the thermal emitter.

10. The IC structure of claim 1, in which the dielectric layer comprises a direct thermal contact between the terminal and the floating contact field plate.

11. A method for fabricating an ambient temperature sensing device using an integrated circuit (IC) structure, the method comprising:
forming an active/passive device in a substrate;
forming a floating contact field plate above a terminal of the active/passive device; and
depositing a dielectric layer between the floating contact field plate and the terminal of the active/passive device.

12. The method of claim 11, in which the active/passive device comprises a bipolar junction transistor (BJT) and the terminal comprises an emitter.

13. The method of claim 11, in which the active/passive device comprises a complementary metal oxide semiconductor (CMOS), diffusion resistor, a CMOS, polysilicon resistor, and/or a CMOS capacitor (MOSCAP).

14. The method of claim 11, in which the active/passive device comprises a diode and the terminal comprises an anode or a cathode.

15. The method of claim 11, in which the dielectric layer comprises silicon nitride (SiN), silicon dioxide (SiO₂), or titanium nitride (TiN).

16. The method of claim 11, in which the floating contact field plate comprises tungsten (W), cobalt (Co), or ruthenium (Ru).

17. The method of claim 11, further comprising a first (M1) metal layer coupled to the floating contact field plate.

18. The method of claim 11, further comprising a first (M1) metal layer comprising a thermal emitter.

19. The method of claim 18, further comprising an emitter plate coupled to the thermal emitter.

20. The method of claim 11, in which the dielectric layer comprises a direct thermal contact between the terminal and the floating contact field plate.
